(19) United States
(12) Patent Application Publication
(10) Pub. No.: US 2024/0421217 A1
(43) Pub. Date: Dec. 19, 2024

(54) SEMICONDUCTOR DEVICE INCLUDING HEAT SHIELD

(71) Applicant: Analog Devices, Inc., Wilmington, MA (US)

(72) Inventors: James G. Fiorenza, Carlisle, MA (US); Daniel Piedra, Somerville, MA (US); Justin Scott Reiter, Norwood, MA (US); Michael Gurr, North Andover, MA (US)

(21) Appl. No.: 18/209,977

(22) Filed: Jun. 14, 2023

(51) Int. Cl. H01L 29/778; H01L 23/373; H01L 29/20; H01L 29/66

(52) U.S. Cl. CPC H01L 29/7783; H01L 23/3736; H01L 23/3738; H01L 29/2003; H01L 29/66462

(57) ABSTRACT

Techniques that separate the heat generation from the active device and that add a thermal heat shield layer between the heat generation and the active device to reduce the channel temperature in the areas that determine the reliability of a semiconductor device.

### FIELD OF THE DISCLOSURE

This document pertains generally, but not by way of limitation, to semiconductor devices, and more particularly, to techniques for constructing gallium nitride devices.

### BACKGROUND

Semiconductors are materials that have a unique ability to conduct electricity, which makes them essential components of electronic devices such as transistors, integrated circuits, and sensors. However, the flow of electric current through a semiconductor generates heat due to the resistance of the material. This heat can increase the temperature of the device, leading to performance degradation and potentially device failure. Therefore, managing heat density in semiconductors is essential to ensure their reliability and longevity.

Thermal resistance is a measure of the ability of a material to dissipate heat. In semiconductors, thermal resistance is a critical factor in managing heat density. It refers to the resistance of the material to the flow of heat from the semiconductor device to its surroundings. Lower thermal resistance means that the heat generated in the device can be more easily dissipated to the environment, reducing the device's temperature.

### SUMMARY OF THE DISCLOSURE

This disclosure describes techniques that separate the heat generation from the active device and that add a thermal heat shield layer between the heat generation and the active device to reduce the channel temperature in the areas that determine the reliability of a semiconductor device. In some examples, the heat shield layer can be aluminum gallium nitride (AlGaN) so that its thermal conductivity can be tuned by the percentage of aluminum in the heat shield layer.

In some aspects, this disclosure is directed to a compound semiconductor heterostructure transistor device having at least one two-dimensional electron gas channel and buried heat shielding, the compound semiconductor heterostructure transistor device comprising: a substrate; an electrode region having at least one gate electrode, the electrode region formed over the substrate; a first buried two-dimensional electron gas (2DEG) channel, wherein the first buried 2DEG channel is more electrically conductive than either a first semiconductor material layer or a second semiconductor material layer formed over the first semiconductor material to form a first compound semiconductor heterostructure; and a buried heat shield layer formed between the electrode region and the buried 2DEG channel.

In some aspects, this disclosure is directed to a method of forming a compound semiconductor heterostructure transistor device having buried heat shielding, the method comprising: forming a field plate region in or adjacent to a substrate; forming an electrode region over the substrate, wherein the electrode region has at least one gate electrode; forming a first buried two-dimensional electron gas (2DEG) channel, wherein the first buried 2DEG channel is more electrically conductive than either a first semiconductor material layer or a second semiconductor material layer formed over the first semiconductor material to form a first compound semiconductor heterostructure; and forming a buried heat shield layer between the electrode region and the buried 2DEG channel.

In some aspects, this disclosure is directed to a semiconductor device having buried heat shielding, the semiconductor device comprising: a substrate; an electrode region formed over the substrate; a buried current carrying layer formed over the substrate; and a buried heat shield layer formed between the electrode region and the buried current carrying layer.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a cross-sectional view of an example an approach to a high-electron mobility transistor (HEMT) device.

FIG. 2 is a cross-sectional view of an example transistor device including a heat shield layer, in accordance with this disclosure.

FIG. 3 is a cross-sectional view of another example transistor device including a heat shield layer, in accordance with this disclosure.

FIG. 4 is a top-down view of an arrangement of an electrode region of a device that includes a buried heat shield layer.

FIG. 5 is a flow diagram of an example of a method for forming a compound semiconductor heterostructure transistor device having buried heat shielding.

FIG. 6 is a cross-sectional view of an example of a transistor device including a heat pad, in accordance with this disclosure.

FIG. 7 is a cross-sectional view of an example of a semiconductor device including a heat shield layer, in accordance with this disclosure.

### DETAILED DESCRIPTION

Managing heat density in semiconductors is essential to ensure their reliability and longevity. The present inventors have recognized that the reliability of a semiconductor device is limited by the high temperature at the surface of the semiconductor device and by electromigration in the ohmic contacts, rather than the effects of the crystal itself, e.g., gallium nitride (GaN) crystal. The present inventors have further recognized a need to improve the reliability of semiconductor devices at higher power densities and, as such, at higher temperatures.

This disclosure describes techniques that separate the heat generation from the active device and that add a thermal heat shield layer between the heat generation and the active device to reduce the channel temperature in the areas that determine the reliability of a semiconductor device. In some examples, the heat shield layer can be aluminum gallium nitride (AlGaN) so that its thermal conductivity can be tuned by the percentage of aluminum in the heat shield layer.

Gallium nitride based semiconductors offer several advantages over other semiconductors as the material of choice for fabricating the next generation of transistors, or semiconductor devices, for use in both high-voltage and high-frequency applications. Gallium nitride (GaN) based semiconductors, for example, have a wide-bandgap that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification systems.

As used in this disclosure, a GaN-based compound semiconductor material can include a chemical compound of elements including GaN and one or more elements from different groups in the periodic table. Such chemical compounds can include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table can also be referred to as Group III and group 15 as Group V. In an example, a semiconductor device can be fabricated from GaN and aluminum indium gallium nitride (AlInGaN).

Heterostructures described herein can be formed as AlN/GaN/AlN hetero-structures, InAlN/GaN heterostructures, AlGaN/GaN heterostructures, or heterostructures formed from other combinations of group 13 and group 15 elements. These heterostructures can form a two-dimensional electron gas (2DEG) at the interface of the compound semiconductors that form the heterostructure, such as the interface of GaN and AlGaN. The 2DEG can form a conductive channel of electrons that can be controllably depleted, such as by an electric field formed by a buried layer of p-type material disposed below the channel. The conductive channel of electrons that can also be controllably enhanced, such as by an electric field formed by a gate terminal disposed above the channel to control a current through the semiconductor device. Semiconductor devices formed using such conductive channels can include high electron mobility transistors.

FIG. 1 is a cross-sectional view of an example of an approach to a high-electron mobility transistor (HEMT) device. The device 100 includes a substrate 102, such as silicon carbide (SiC). A first semiconductor layer 104, such as a layer of aluminum nitride (AlN), is formed over the substrate 102. A second semiconductor layer 106, such as GaN, is formed over the first semiconductor layer 104.

A third semiconductor layer 108, such as AlGaN, is formed over the second semiconductor layer 106, thereby forming a heterostructure and a 2DEG channel 110, which is indicated by the dotted line. The device 100 can include a passivation layer 112, such as silicon nitride (SiN) or silicon oxide.

A source electrode 114 and a drain electrode 116 are electrically coupled to the 2DEG channel 110. A gate electrode 118 is formed over the third semiconductor layer 108.

The device 100 can further include a field plate (FP) 120. The field plate 120 can help control the electric field at the surface of the device 100, such as the electric field between the gate and drain, or the electric field between the source and drain. In the example shown, the field plate 120 is formed over the passivation layer 112.

A peak electric field occurs adjacent the gate electrode 118, generating a hot spot 122, which can limit reliability. In addition, trapping near the gate, electromigration of ohmic contacts, and trapping in the dielectric can limit reliability.

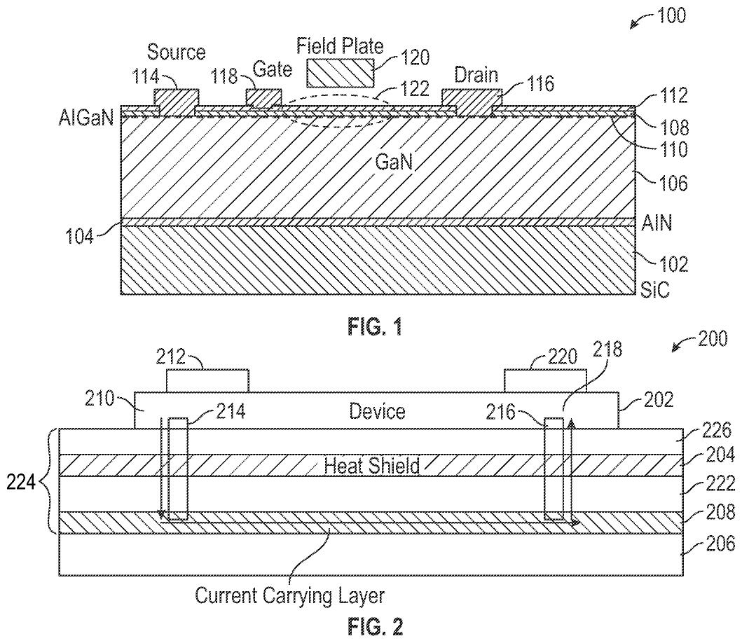

FIG. 2 is a cross-sectional view of an example transistor device including a heat shield layer, in accordance with this disclosure. The transistor device 200 separates the heat generation from the active device 202 and includes a buried thermal heat shield layer, namely a buried semiconductor layer 204, between the heat generation and the active device 202 to reduce a channel temperature in the areas that determine the reliability of a semiconductor device. The active device 202 can be a semiconductor device such as a resistor or diode in which the current and bulk of the heat generation is separated from the device contacts by a heat shield layer.

In some examples, the buried third semiconductor layer 204 includes AlGaN, where the percentage of aluminum can be tuned to adjust the thermal resistance of the heat shield layer. The thermal resistance of AlGaN is known to be a strong function of the aluminum mole fraction because of alloy scattering. The AlGaN layer can use an aluminum fraction to minimize the thermal conductivity of the material so that the AlGaN layer is as thermally resistive as desired. In heat shield layers that include AlGaN, the aluminum content can be in a range of 25-80% aluminum. In contrast, the aluminum content in an AlGaN layer such as the fifth semiconductor layer 320 would normally be in a range of 15-30% aluminum.

The transistor device 200 includes a substrate 206, such as SiC. A buried first semiconductor layer 208 is formed over the substrate 206. The buried first semiconductor layer 208 acts as a current carrying layer that carries current (indicated by arrows) from a first region 210 in the active device 202 and under a first contact 212 to the buried first semiconductor layer 208. In the example shown in FIG. 2, a first via 214 can carry the current from the first region 210 to the buried first semiconductor layer 208. The buried first semiconductor layer 208 can carry the current to a second via 216, which then carries the current to a second region 218 in the active device 202 and under a second contact 220. The buried first semiconductor layer 208 acts as a buried current carrying channel. A second semiconductor layer 222 can be formed over the buried first semiconductor layer 208.

A buried third semiconductor layer 204 can be formed over the second semiconductor layer 222. In accordance with this disclosure, the buried third semiconductor layer 204 is configured to act as a buried thermal heat shield layer, such as having a thickness of about 10 nanometers to 10 micrometers. The buried third semiconductor layer 204 is more thermally resistive than the substrate 206 and the other epitaxial layers 224 around it. A fourth semiconductor layer 226 can be formed over the buried third semiconductor layer 204.

As mentioned above, the reliability of a semiconductor device is limited by the high temperature at the surface of the device 202 and by electromigration in the ohmic contacts. By using the techniques of FIG. 2, heat is generated in the buried current carrying channel, namely the buried first semiconductor layer 208, and a buried heat shield layer is positioned between the heat generation and the active device 202 to reduce the channel temperature in the areas that determine the reliability of the transistor device 200.

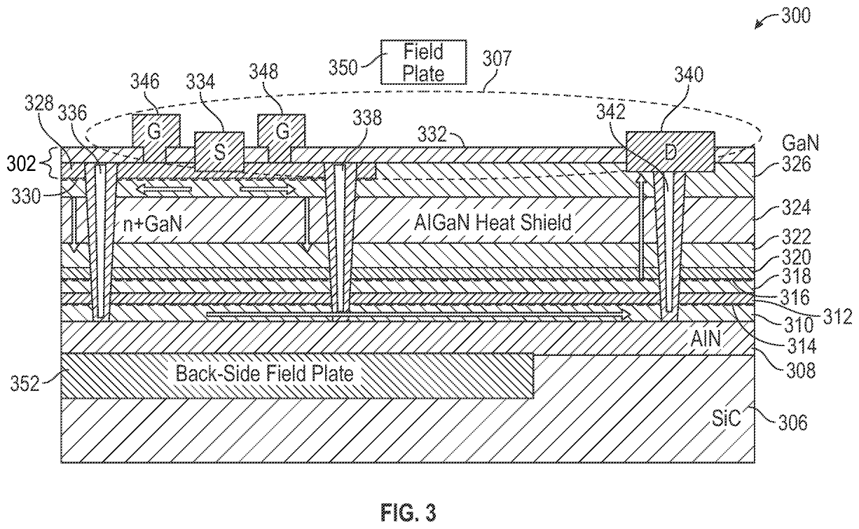

FIG. 3 is a cross-sectional view of another example of a transistor device including a heat shield layer, in accordance with this disclosure. The transistor device 300 separates the heat generation from the active device 302 and includes a buried thermal heat shield layer, namely a buried semiconductor layer 324, between the heat generation and the active device 302 to reduce a channel temperature in the areas that determine the reliability of a semiconductor device.

The transistor device 300 includes a substrate 306, such as SiC. A first semiconductor layer 308, such as AlN, is formed over the substrate 306. A second semiconductor layer 310, such as GaN, is formed over the first semiconductor layer 308. A third semiconductor layer 312, such as AlGaN, is formed over the second semiconductor layer 310. Together, the second semiconductor layer 310 and the third semiconductor layer 312 form a GaN-based heterostructure that results in a first buried 2DEG channel 314 (shown in dashed line), where the first buried 2DEG channel 314 is a buried current carrying channel. The buried first 2DEG channel 314 is more electrically conductive than either the second semiconductor layer 310 or the third semiconductor layer 312.

The transistor device 300 includes another buried current carrying channel. A fourth semiconductor layer 318, such as GaN, is formed over the third semiconductor layer 312. A fifth semiconductor layer 320, such as AlGaN, is formed over the fourth semiconductor layer 318. Together, the fourth semiconductor layer 318 and the fifth semiconductor layer 320 form another GaN-based heterostructure that results in a second buried 2DEG channel 316 (shown in dashed line), where the second buried DEG channel 316 is a buried current carrying channel. A sixth semiconductor layer 322, e.g., GaN, can be formed over the fifth semiconductor layer 320.

Although two buried current carrying channels are shown, some examples can include only one current carrying channel. Other examples can include more than two buried current carrying channels. These buried current carrying channels push the high electric field into the epitaxial layers and isolate the electric field away from the surface, where it could cause current collapse and reliability problems.

The transistor device 300 can include a buried seventh semiconductor layer 324 formed over the sixth semiconductor layer 322, where the buried seventh semiconductor layer 324, e.g., AlGaN acts as a thermal heat shield layer. The buried seventh semiconductor layer 324 spatially separates the heat generation in the current carrying layers from the active device and also adds a thermal shield between the heat generation and active device to reduce the channel temperature in the areas that determine the device reliability.

In some examples, the buried seventh semiconductor layer 324 includes AlGaN, where the percentage of aluminum can be tuned to adjust the thermal resistance of the heat shield layer. The thermal resistance of AlGaN is known to be a strong function of the aluminum mole fraction because of alloy scattering. The AlGaN layer can use an aluminum fraction to minimize the thermal conductivity of the material so that the AlGaN layer is as thermally resistive as desired.

In heat shield layers that include AlGaN, the aluminum content can be in a range of 25-80% aluminum. In contrast, the aluminum content in an AlGaN layer such as the fifth semiconductor layer 320 would normally be in a range of 15-30% aluminum.

An eighth semiconductor layer 326, e.g., GaN, is formed over the buried seventh semiconductor layer 324. In the example shown, a portion of the eighth semiconductor layer 326 can be removed, e.g., via etching, to form a notch and a ninth semiconductor layer 328, e.g., AlGaN, can be formed within the notch. The ninth semiconductor layer 328 and the eighth semiconductor layer 326 form another 2DEG channel 330 (shown in dashed line), e.g., a topside 2DEG channel.

In other examples, the ninth semiconductor layer 328, e.g., AlGaN, can be grown on the eighth semiconductor layer 326, e.g., GaN, (planar, no vias or notches). Then, the ninth semiconductor layer 328 can be patterned and some of the region between the gate and the drain on the ninth semiconductor layer 328 can be etched away so that this top 2DEG is not connecting the source to the drain.

The transistor device 300 can include a passivation layer 332, such as silicon nitride (SiN) or silicon oxide, which is formed over the eighth semiconductor layer 326 and the ninth semiconductor layer 328.

The transistor device 300 can include an electrode region 307 formed over the substrate 306, where the electrode region 307 includes a source contact, a drain contact, and a gate contact. A source electrode 334 can be in electrical contact with the ninth semiconductor layer 328 and electrically coupled to the topside DEG channel 330. Vias 336, 338 can be electrically coupled between the ninth semiconductor layer 328 and the second semiconductor layer 310 to carry current (illustrated using arrows) from the topside of the device to the buried current carrying channels.

Similarly, a drain electrode 340 can be in electrical contact with the eighth semiconductor layer 326. A via 342 can be electrically coupled between the ninth semiconductor layer 328 and the second semiconductor layer 310 to carry current from the buried current carrying channels to the topside of the device.

The transistor device 300 can include a first gate electrode 346 formed above the ninth semiconductor layer 328 and adjacent a first side of the source electrode 334. In some examples, the transistor device 300 can include a second gate electrode 348 formed above the ninth semiconductor layer 328 and adjacent a second side of the source electrode 334.

In some examples, the transistor device 300 can include a topside field plate 350. The topside field plate 350 can help control the electric field at the surface of the device 300, such as the electric field between the gate and drain, or the electric field between the source and drain. In the example shown, the field plate 350 is formed over the passivation layer 332.

In addition to or instead of the topside field plate 350, the transistor device 300 can include a backside field plate 352. In some examples, a portion of the substrate 306 can be implanted with a semiconductor material or metal to operate as a backside field plate 352. In other examples, material can be removed from a portion of the substrate 306, e.g., via etching, and then a semiconductor material or metal can be formed in the portion to operate as a backside field plate 352. In some examples, the backside field plate 352 can be formed over the substrate 306.

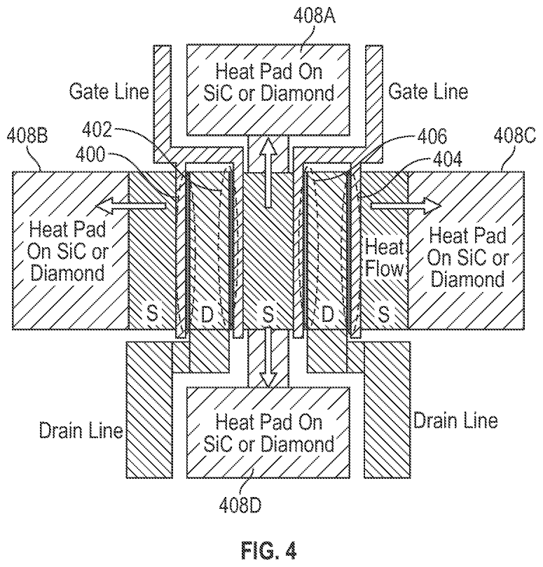

FIG. 4 is a top-down view of an arrangement of an electrode region of a device that includes a buried heat shield layer. The electrode region shown in FIG. 4 includes a source electrode(S) and a drain electrode (D), such as the source electrode 334 and the drain electrode 340 of FIG. 3. The additional source electrodes in FIG. 4 represent additional transistor devices, e.g., a symmetrical device. Hot spots on the device, such as the transistor device 300 of FIG. 3, are represented by regions 400-406.

The present inventors have recognized the desirability of drawing heat away from the regions 400-406. In the example shown, one or more heat pads 408A-408D can be included, such as thermally coupled to a corresponding source electrode. The heat can then be drawn away from the regions 400-406 and under the gate electrode. The heat pad can be metallic, such as copper. The heat pad can be 20-50 micrometers thick, for example. Additionally, the metal is placed on the source electrodes.

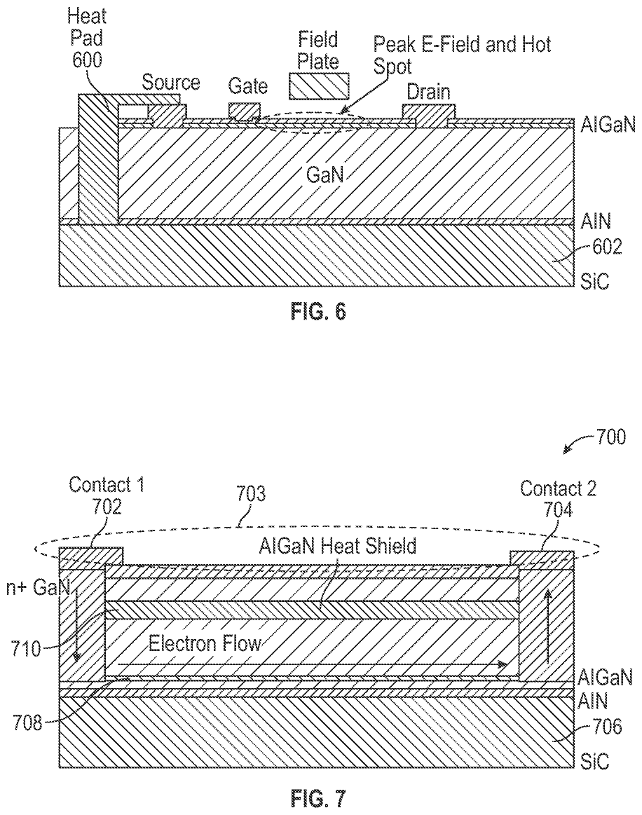

The heat pads 408A-408D can be physically coupled to the substrate, e.g., such as the transistor device 300 of FIG. 3. For example, various semiconductor layers can be etched and the heat pads 408A-408D can be placed on the substrate, e.g., a SiC substrate. Drawing the heat away can help the thermal resistance remain low at the top of the device. The vias etched to place the head pads can be etched through the heat shield layer. The heat pad metal can be placed on the source electrode and extend down to contact the substrate, such as shown in FIG. 6.

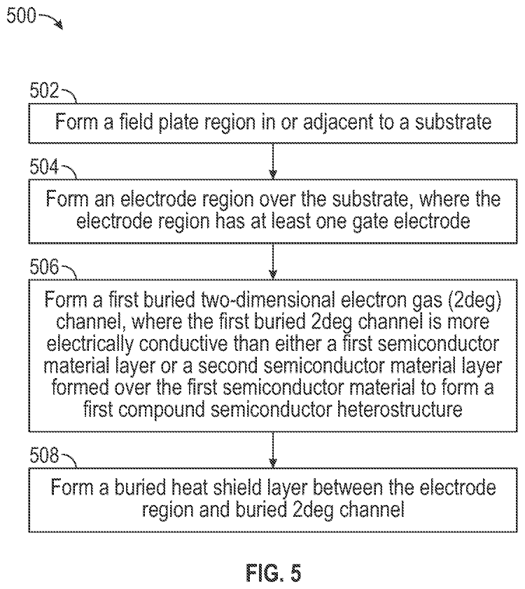

FIG. 5 is a flow diagram of an example of a method 500 for forming a compound semiconductor heterostructure transistor device having buried heat shielding. At block 502, the method 500 includes forming a field plate region in or adjacent to a substrate. For example, a backside field plate 352 can be formed in or adjacent to the substrate 306 of FIG. 3.

At block 504, the method 500 includes forming an electrode region over the substrate, where the electrode region has at least one gate electrode. For example, the transistor device 300 of FIG. 3 includes an electrode region 307 having at least one of the first gate electrode 346 and the second gate electrode 348.

At block 506, the method 500 includes forming a first buried two-dimensional electron gas (2DEG) channel, wherein the first buried 2DEG channel is more electrically conductive than either a first semiconductor material layer or a second semiconductor material layer formed over the first semiconductor material to form a first compound semiconductor heterostructure. For example, the transistor device 300 of FIG. 3 includes a buried 2DEG channel 314 formed by second semiconductor layer 310 and third semiconductor layer 312.

At block 508, the method 500 includes forming a buried heat shield layer between the electrode region and the buried 2DEG channel. For example, the method 500 includes forming the buried seventh semiconductor layer 324 between the electrode region 307 and the buried 2DEG channel 314.

In some examples, the method 500 includes forming a third semiconductor material layer over a fourth semiconductor material layer, wherein the fourth semiconductor material layer is formed over the substrate, to form a second compound semiconductor heterostructure having a topside second 2DEG channel, wherein the topside second 2DEG channel is more electrically conductive than either the third semiconductor material layer or the fourth semiconductor material layer.

In some examples, forming the electrode region over the substrate includes electrically coupling a drain electrode to the first semiconductor layer, electrically coupling a source electrode to the topside second 2DEG channel, and forming a gate electrode over the third semiconductor material layer.

In some examples, the method 500 includes coupling one or more heat pads to the source electrode. In some examples, the heat pad(s) includes copper, e.g., having a thickness in range of 20-50 micrometers.

In some examples, the method 500 includes forming a second buried two-dimensional electron gas (2DEG) channel, wherein the second buried 2DEG channel is more electrically conductive than either a sixth semiconductor material layer or a seventh semiconductor material layer formed over the sixth semiconductor material to form a second compound semiconductor heterostructure.

FIG. 6 is a cross-sectional view of an example of a transistor device including a heat pad, in accordance with this disclosure. The vias etched to place the head pad 600 can be etched through the heat shield layer. The heat pad metal can be placed on the source electrode and extend down to contact the substrate 602.

FIG. 7 is a cross-sectional view of an example of a semiconductor device including a heat shield layer, in accordance with this disclosure. The heat shield techniques of this disclosure are not limited to transistor devices. Rather, the heat shield layer can be included in other semiconductor devices, such as resistors, diodes, and other two-terminal devices.

A semiconductor device 700 is depicted in FIG. 7. The semiconductor device 700, e.g., a resistor or diode, includes a first contact 702 and a second contact 704 forming an electrode region 703. The electrode region 703 is formed over a substrate 706, e.g., SiC. Current (illustrate using arrows) flows downward from the first contact 702 through, for example, an n+ GaN region, to a buried current carrying layer 708 formed over the substrate 706. The buried current carrying layer 708 carries the current to another n+ GaN region and upward to the second contact 704.

The semiconductor device 700 includes a buried heat shield layer 710 formed between the electrode region 703 and the buried current carrying layer 708. In some examples, the buried heat shield layer 710 includes aluminum gallium nitride. In some examples, an aluminum content of the aluminum gallium nitride is within a range of 25-80%.

### Various Notes

Each of the non-limiting aspects or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in a aspect are still deemed to fall within the scope of that aspect. Moreover, in the following aspects, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the aspects. Also, in the above Detailed Description, various features may be grouped together to streamline the disclosure. This should not be interpreted as intending that an unclaimed disclosed feature is essential to any aspect. Rather, inventive subject matter may lie in less than all features of a particular disclosed embodiment. Thus, the following aspects are hereby incorporated into the Detailed Description as examples or embodiments, with each aspect standing on its own as a separate embodiment, and it is contemplated that such embodiments may be combined with each other in various combinations or permutations. The scope of the invention should be determined with reference to the appended aspects, along with the full scope of equivalents to which such aspects are entitled.

1. A compound semiconductor heterostructure transistor device having at least one two-dimensional electron gas channel and buried heat shielding, the compound semiconductor heterostructure transistor device comprising:
a substrate;
an electrode region having at least one gate electrode, the electrode region formed over the substrate;
a first buried two-dimensional electron gas (2DEG) channel, wherein the first buried 2DEG channel is more electrically conductive than either a first semiconductor material layer or a second semiconductor material layer formed over the first semiconductor material to form a first compound semiconductor heterostructure; and
a buried heat shield layer formed between the electrode region and the buried 2DEG channel.

2. The compound semiconductor heterostructure transistor device of claim 1, comprising:
a third semiconductor material layer formed over a fourth semiconductor material layer, wherein the fourth semiconductor material layer is formed over the substrate, to form a second compound semiconductor heterostructure having a topside second 2DEG channel, wherein the topside second 2DEG channel is more electrically conductive than either the third semiconductor material layer or the fourth semiconductor material layer.

3. The compound semiconductor heterostructure transistor device of claim 2, wherein the electrode region includes:
a drain electrode electrically coupled to the first semiconductor layer;
a source electrode electrically coupled to the topside second 2DEG channel; and
a gate electrode formed over the third semiconductor material layer.

4. The compound semiconductor heterostructure transistor device of claim 2, wherein the heat shield layer is formed between the fourth semiconductor material layer and the second semiconductor material layer, and wherein the heat shield layer includes a fifth semiconductor material layer.

5. The compound semiconductor heterostructure transistor device of claim 1, wherein the buried heat shield layer includes aluminum gallium nitride.

6. The compound semiconductor heterostructure transistor device of claim 5, wherein an aluminum content of the aluminum gallium nitride is within a range of 25-80%.

7. The compound semiconductor heterostructure transistor device of claim 1, wherein the electrode region includes a source electrode, the compound semiconductor heterostructure transistor device comprising:
at least one heat pad coupled to the source electrode.

8. The compound semiconductor heterostructure transistor device of claim 7, wherein the at least one heat pad includes copper.

9. The compound semiconductor heterostructure transistor device of claim 8, wherein the copper has a thickness in range of 20-50 micrometers.

10. The compound semiconductor heterostructure transistor device of claim 1, comprising:
a second buried two-dimensional electron gas (2DEG) channel, wherein the second buried 2DEG channel is more electrically conductive than either a sixth semiconductor material layer or a seventh semiconductor material layer formed over the sixth semiconductor material to form a second compound semiconductor heterostructure.

11. A method of forming a compound semiconductor heterostructure transistor device having buried heat shielding, the method comprising:
forming a field plate region in or adjacent to a substrate;
forming an electrode region over the substrate, wherein the electrode region has at least one gate electrode;
forming a first buried two-dimensional electron gas (2DEG) channel, wherein the first buried 2DEG channel is more electrically conductive than either a first semiconductor material layer or a second semiconductor material layer formed over the first semiconductor material to form a first compound semiconductor heterostructure; and
forming a buried heat shield layer between the electrode region and the buried 2DEG channel.

12. The method of claim 11, comprising:
forming a third semiconductor material layer over a fourth semiconductor material layer, wherein the fourth semiconductor material layer is formed over the substrate, to form a second compound semiconductor heterostructure having a topside second 2DEG channel, wherein the topside second 2DEG channel is more electrically conductive than either the third semiconductor material layer or the fourth semiconductor material layer.

13. The method of claim 12, wherein forming the electrode region over the substrate includes:
electrically coupling a drain electrode to the first semiconductor layer;
electrically coupling a source electrode to the topside second 2DEG channel; and
forming a gate electrode over the third semiconductor material layer.

14. The method of claim 11, wherein forming an electrode region over the substrate includes forming a source electrode, the method further comprising:
coupling at least one heat pad to the source electrode.

15. The method of claim 14, wherein the at least one heat pad includes copper.

16. The method of claim 15, wherein the copper has a thickness in range of 20-50 micrometers.

17. The method of claim 11, comprising:
forming a second buried two-dimensional electron gas (2DEG) channel, wherein the second buried 2DEG channel is more electrically conductive than either a sixth semiconductor material layer or a seventh semiconductor material layer formed over the sixth semiconductor material to form a second compound semiconductor heterostructure.

18. A semiconductor device having buried heat shielding, the semiconductor device comprising:
a substrate;
an electrode region formed over the substrate;
a buried current carrying layer formed over the substrate; and
a buried heat shield layer formed between the electrode region and the buried current carrying layer.

19. The semiconductor device of claim 18, wherein the buried heat shield layer includes aluminum gallium nitride.

20. The semiconductor device of claim 19, wherein an aluminum content of the aluminum gallium nitride is within a range of 25-80%.
